(19) United States
(12) Patent Application Publication
(10) Pub. No.: US 2026/0250123 A1
(43) Pub. Date: Aug. 27, 2026

(54) THREE DIMENSIONAL TRACE FOR MICRO-ELECTROMECHANICAL SYSTEM (MEMS) DEVICES

(71) Applicant: Lumentum Operations LLC, San Jose, CA (US)

(72) Inventors: Wenlin JIN, Ottawa (CA); John Michael MILLER, Ottawa (CA); Parsoua ABEDINI SOHI, Nepean (CA)

(21) Appl. No.: 19/192,161

(22) Filed: Apr. 28, 2025

Related U.S. Application Data
(60) Provisional application No. 63/763,667, filed on Feb. 26, 2025.

(51) Int. Cl. B81B 7/00; B81C 1/00; G02B 26/08

(52) U.S. Cl. CPC B81B 7/0006; B81C 1/00142; G02B 26/0833; B81B 2201/042; B81B 2203/0109; B81B 2203/0136; B81B 2203/0307; B81B 2203/04; B81B 2207/07; B81C 2201/013; B81C 2201/0174; B81C 2203/03

(57) ABSTRACT

In some implementations, a micro-electromechanical system (MEMS) mirror device includes a hinged mirror; a first set of actuating elements, wherein the first set of actuating elements is associated with a first set of electrodes connected to a first bus; a second set of actuating elements, wherein the second set of actuating elements is associated with a second set of electrodes connected to a second bus; and a set of three-dimensional traces electrically connecting the second set of electrodes to the second bus without touching the first bus, wherein a three-dimensional trace, of the set of three-dimensional traces, includes a pair of posts extending vertically from the second bus and the second set of electrodes, respectively, and includes a bridge connecting the pair of posts.

### CROSS-REFERENCE TO RELATED APPLICATION

This Patent Application claims priority to U.S. Provisional Patent Application No. 63/763,667, filed on February 26, 2025, and entitled "MICRO-ELECTROMECHANICAL SYSTEM (MEMS) MIRROR ARRAY WITH THREE-DIMENSIONAL TRACE." The disclosure of the prior Application is considered part of and is incorporated by reference into this Patent Application.

### TECHNICAL FIELD

The present disclosure relates generally to micro-electromechanical system (MEMS) devices and to a three-dimensional trace for MEMS devices.

### BACKGROUND

A micro-electromechanical system (MEMS) device is a micro-sized mechanical structure that may include a mirror for reflecting light. When the MEMS device is actuated, the mirror may be tilted about an axis, which may cause an optical beam that was falling upon the mirror and reflecting in one direction to fall upon the mirror and reflect in a different direction. The MEMS device may actuate (e.g., tilt) the mirror using an electrical impulse, such as by using a rotor-comb actuator.

### SUMMARY

In some implementations, a micro-electromechanical system (MEMS) mirror device includes a hinged mirror; a first set of actuating elements, wherein the first set of actuating elements is associated with a first set of electrodes connected to a first bus; a second set of actuating elements, wherein the second set of actuating elements is associated with a second set of electrodes connected to a second bus; and a set of three-dimensional traces electrically connecting the second set of electrodes to the second bus without touching the first bus, wherein a three-dimensional trace, of the set of three-dimensional traces, includes a pair of posts extending vertically from the second bus and the second set of electrodes, respectively, and includes a bridge connecting the pair of posts.

In some implementations, a MEMS device includes a movable element; and an actuating layer disposed below the movable element and comprising: a first set of actuating elements configured to move the movable element in a first direction, wherein the first set of actuating elements is associated with a first set of electrodes connected to a first bus via a first set of electrical traces, a second set of actuating elements configured to move the movable element in a second direction, wherein the second set of actuating elements is associated with a second set of electrodes connected to a second bus via a second set of electrical traces, wherein the second set of electrical traces is disposed at least partially above the first bus.

In some implementations, a method includes forming, by a manufacturing device on a first substrate, an electrode layer of a MEMS device, wherein the electrode layer includes a first electrode and a second electrode, wherein the first electrode is connected to a first bus and the second electrode is connected to a second bus; forming, by the manufacturing device, a first post on top of the second electrode and a second post on top of the second bus; forming, by the manufacturing device on a second substrate, a bridge layer; and wafer bonding, by the manufacturing device, the bridge layer onto the first post and the second post, such that the first post is electrically connected to the second post by the bridge layer.

### BRIEF DESCRIPTION OF THE DRAWINGS

FIGS. 1A-1C are diagrams of example MEMS mirror devices.

FIGS. 2A and 2B are plan views of example MEMS arrays/250.

FIGS. 3A-3C are diagrams of examples of assembling an optical device with a three- dimensional trace.

FIG. 4 is a flowchart of an example process associated with manufacturing a MEMS device with a three-dimensional trace.

### DETAILED DESCRIPTION

The following detailed description of example implementations refers to the accompanying drawings. The same reference numbers in different drawings may identify the same or similar elements.

An optical system may direct an optical beam (e.g., a laser beam) toward a target. For example, the optical system may include an optical communications system that directs an optical beam toward an optical device for communications, an optical measurement system that directs an optical beam toward a target to measure a reflection of the optical beam, or an optical manufacturing system that directs an optical beam toward a target to effectuate a manufacturing process (e.g., laser cutting or laser welding), among other examples. In one example, a vehicle, such as a semiautonomous or fully autonomous vehicle, may use a light detection and ranging (LIDAR) system to detect objects (e.g., other vehicles, pedestrians, or road debris) in a path of the vehicle. A typical LIDAR system includes a beam deflection unit that deflects both projected optical beams and reflected optical beams. Similarly, an optical communications system may include a beam deflection unit to direct an optical beam toward a desired optical path (e.g., as part of an optical circuit switch) or an optical manufacturing system may include a beam deflection unit to direct an optical beam toward a particular area of a target.

In some cases, an optical system may use one or more micro-electromechanical system (MEMS) devices to deflect optical beams. A MEMS device may use a multi-layer comb actuator structure (e.g., comprising a stator comb actuator and a rotor comb actuator) to provide a driving torque to tilt a mirror on a hinge of the MEMS device about an axis. Additionally, or alternatively, a MEMS device may use a set of parallel plates as actuating elements to drive an optical element, such as a mirror. MEMS devices may be deployed with multiple switching elements arranged in linear arrays or two-dimensional arrays. Electrodes are provided in the MEMS devices to provide driving voltages to X-axis switching electrodes and Y-axis switching electrodes, thereby providing the MEMS device with actuation to tilt an optical element (e.g., a mirror) about an X-hinge (e.g., about a first axis defined by a first hinge) and a Y-hinge (e.g., about a second axis defined by the second hinge). In some examples, the second axis may be orthogonal to the first axis. Such a MEMS device may be manufactured from two layers of materials, a first layer providing the electrodes and a second layer providing the mirror and hinges, thereby enabling miniaturization of the MEMS device.

However, such a configuration, using planar traces on the electrode layer, with a parallel X-bus and Y-bus for the X-axis switching electrodes and the Y-axis switching electrodes, respectively, results in an excessively large electrical trace plan on the electrode layer. As a sizeof an optical element array (e.g., a MEMS device with multiple mirrors) increases, a planar electrical trace routing approach uses increasingly large amounts of space to separately route the X-axis switching electrodes and the Y-axis switching electrodes to the parallel X-bus and Y-bus, respectively. Accordingly, it is desirable for a MEMS device to have an electrical trace configuration for large quantities of optical elements without the electrode layer being excessively large to accommodate electrical traces.

Some implementations described herein provide a MEMS array with a three- dimensional trace. For example, a MEMS array may include a hinged optical element (e.g., a mirror), a first set of actuating elements (e.g., tilting combs) with a first set of electrodes electrically connected to a first linear bus, and a second set of actuating elements (e.g., tilting combs) with a second set of electrodes electrically connected to a second linear bus. To reduce electrical trace routing space on an electrode layer of the MEMS array, electrical traces connecting the second set of electrodes to the second linear bus may include three-dimensional traces that cross over the first linear bus without touching the first linear bus. A three- dimensional trace may include a set of posts and a bridge connecting the set of posts and may be manufactured integrally with the electrode layer or partially integrally with the electrode layer, in some implementations. As a result, by using three-dimensional traces for electrical connections to the second linear bus, the MEMS array can be manufactured in increasingly small packages, thereby facilitating increasing miniaturization of optical devices and systems.

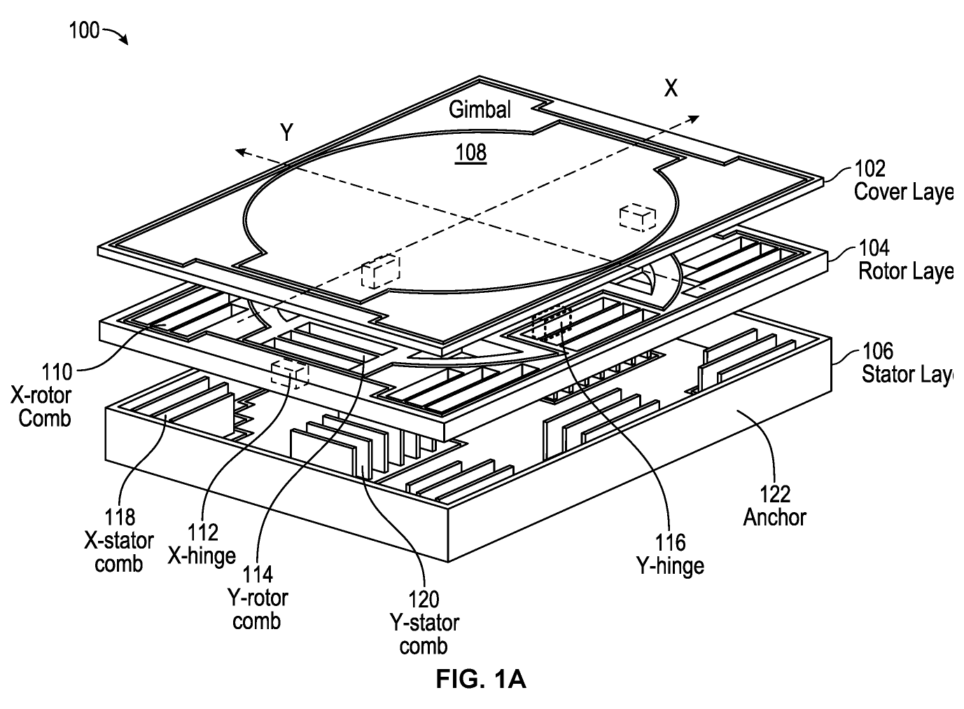

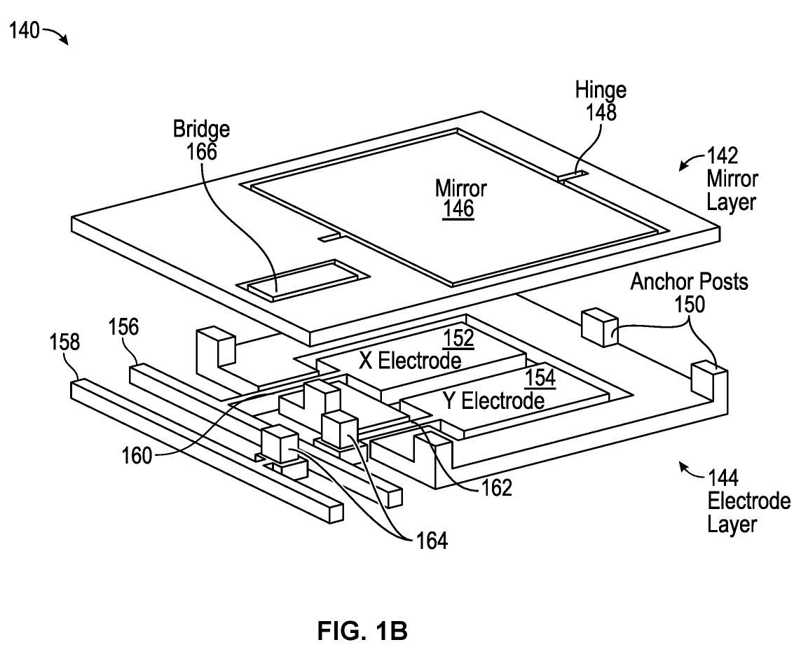

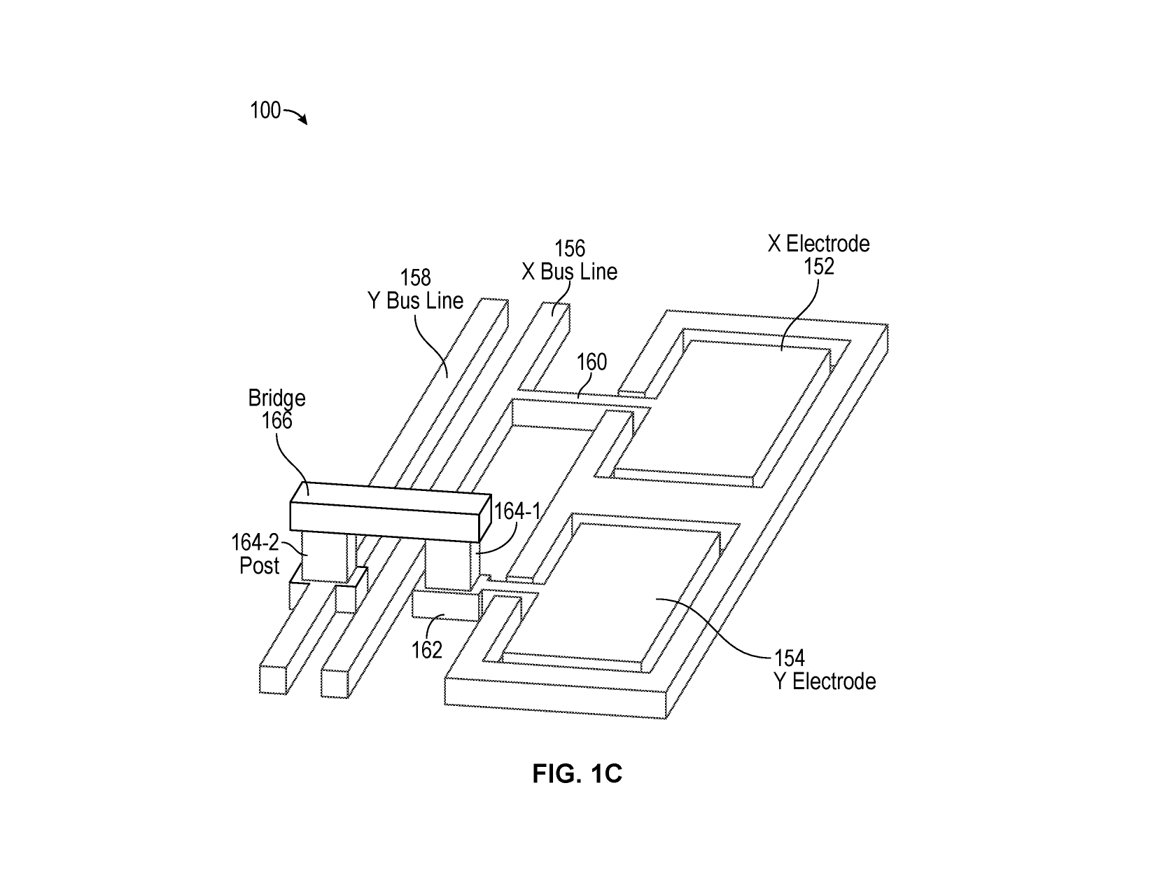

FIGS. 1A-1C are diagrams of example MEMS mirror devices. As shown in FIG. 1A, a MEMS mirror device 100 may include a three-layer MEMS mirror device that includes a cover layer 102, a rotor layer 104, and a stator layer 106. The cover layer 102 may include a MEMS mirror 108, that is tiltable around an X-axis and around a Y-axis. Although some implementations are described herein in terms of a MEMS mirror device, other types of MEMS devices are contemplated, such as MEMS devices with other types of optical elements (e.g., prisms, switches, filters, gratings, or lens). Although some implementations are described herein in terms of a two-layer or three-layer MEMS mirror devices, other configurations are contemplated.

In some implementations, the rotor layer 104 includes an X-rotor comb 110, an X-hinge 112, a Y-rotor comb 114, and a Y-hinge 116. In some implementations, the stator layer 106 includes an X-stator comb 118, a Y-stator comb 120, and an anchor 122. In a MEMS device, a rotor and stator may be intermeshed to actuate a MEMS element of the MEMS device. For example, in the MEMS mirror device 100, the X-rotor comb 110 and the X-stator comb 118 are intermeshed to tilt the MEMS mirror 108 about the X-hinge 112 and the X-axis. Similarly, the Y- rotor comb 114 and the Y-stator comb 120 are intermeshed to tilt the MEMS mirror 108 about the Y-hinge 116 and the Y-axis. Although some implementations are described herein in terms of a comb-type of MEMS device, other types of MEMS devices are contemplated, such as parallel plate MEMS devices. For example, rather than X-rotor/stator combs 110, 118 and Y rotor/stator combs 114, 120, a MEMS device may include other types of actuating elements or movable elements.

As shown in FIGS. 1B and 1C, the electrode routing layers of a MEMS mirror device 140 may be a two layer MEMS mirror device, which includes a mirror layer 142 and an electrode layer 144. In some implementations, the mirror layer 142 includes a MEMS mirror 146 and a hinge 148. In some implementations, the electrode layer 144 includes a set of anchor posts 150 (e.g., that support the mirror layer 142), an X-electrode 152, a Y-electrode 154, an X- bus 156, and a Y-bus 158. The X-electrode 152 and the Y-electrode 154 may apply a voltage to cause actuation to tilt the MEMS mirror 146 about the hinge 148. Here, the X components (e.g., the X-electrode 152 and the X-bus 156) may be associated with tilting mirrors in a first direction about an axis and the Y components (e.g., the Y-electrode 154 and the Y-bus 158) may be associated with tilting mirrors in a second direction about the axis (e.g., when an amount of displacement that each electrode can achieve is less than a total amount of displacement that the mirrors are to achieve). Additionally, or alternatively, rather than the X components and the Y components being associated with tilting the mirror 146 about different axes or tilting mirrors in different directions about the same axis, the X components and the Y components may be associated with tilting respective mirrors or other optical elements about respective axes. For example, the X components may be associated with tilt of a first subset of mirrors and the Y components may be associated with tilt of a second subset of mirrors. Many other configurations are contemplated in which approximately parallel busses connected to linearly arranged electrodes are possible, among other examples.

In a MEMS mirror array, many MEMS mirror devices 140 may be connected to the X- bus 156 and the Y-bus 158 to actuate respective mirrors 146. The X-electrode 152 and the Y- electrode 154 may enable individual addressability of the respective mirrors 146 of the respective MEMS mirror devices 140 of a MEMS mirror array.

In some implementations, the X-bus 156 and the Y-bus 158 may be arranged in a parallel, planar arrangement. For example, as shown in FIG. 1B, the X-bus 156 and the Y-bus 158 are disposed parallel to each other and, in some implementations, orthogonal to an X-trace 160 and a Y-trace 162 of the X-electrode 152 and the Y-electrode 154, respectively. Because of the parallel, planar arrangement of the X-bus 156 and the Y-bus 158, the X-trace 160 can connect, in the plane of the electrode layer 144, directly to the X-bus 156. However, the X-bus 156 is disposed between the Y-bus 158 and the Y-electrode 154. As a result, the Y-trace 162 cannot connect from the Y-electrode 154 to the Y-bus 158 in the plane of electrode layer 144.

In some implementations, the Y-trace 162 is a three-dimensional trace that extends out of the plane of the electrode layer 144. For example, the Y-trace 162 includes a pair of posts 164 and a bridge 166. In this case, a first post 164-1 extends vertically (e.g., orthogonally to a plane of the electrode layer 144) from the Y-electrode 154 (or a planar portion of the Y-trace 162 extending from the Y-electrode 154 in the plane of the electrode layer 144) and a second post 164 extends vertically from the Y-bus 158. The bridge 166 extends horizontally (e.g., in a plane parallel to and above the electrode layer 144, such as in an opening of the mirror layer 142 that is disposed to receive the bridge 166) between the first post 164-1 and the second post 164-2. In this way, the bridge 166 electrically connects the first post 164-1 and the second post 164-2 without making contact with the X-bus 156 and electrically connects the Y-electrode 154 to the Y-bus 158 without making contact with the X-bus 156. In some implementations, the bridge may include a silicon material, a conductor material (e.g., a metal material), or a combination thereof.

As indicated above, FIGS. 1A-iC are provided as examples. Other examples may differ from what is described with regard to FIGS. 1A-1C.

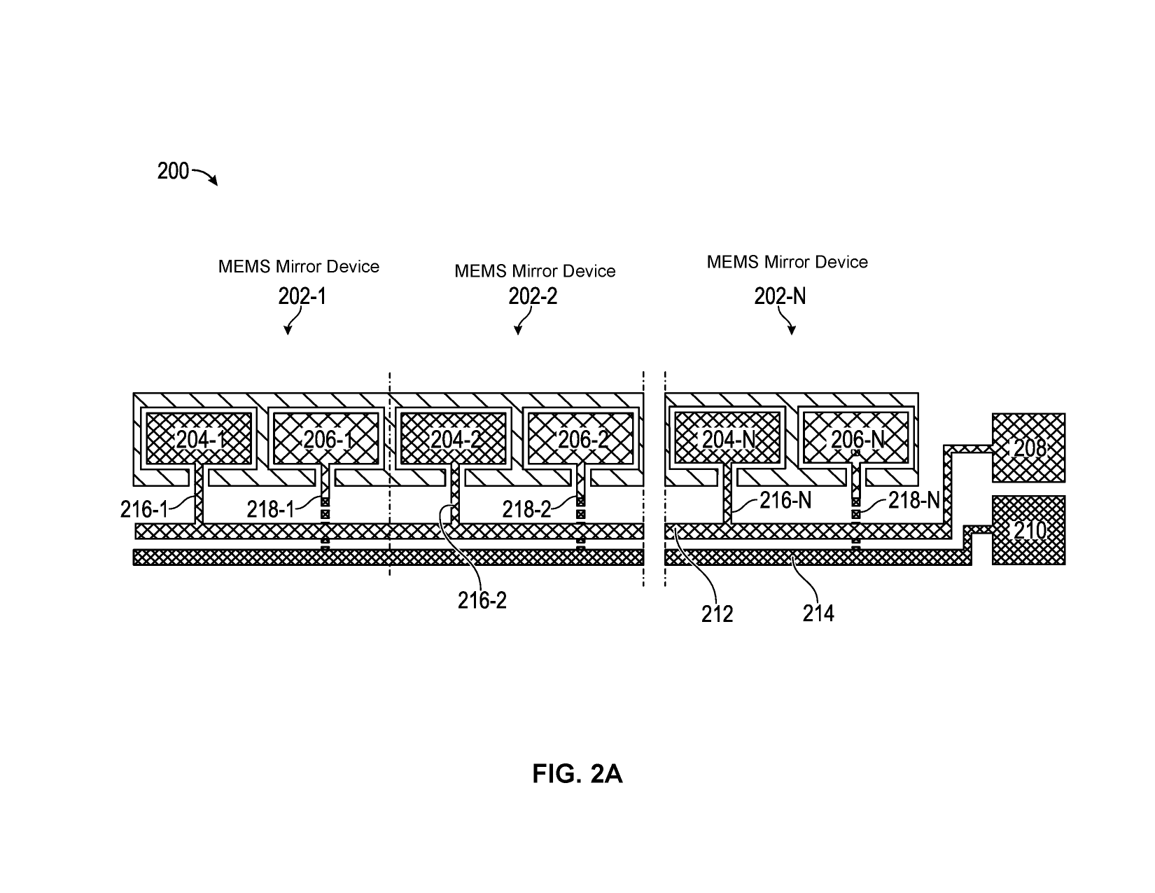

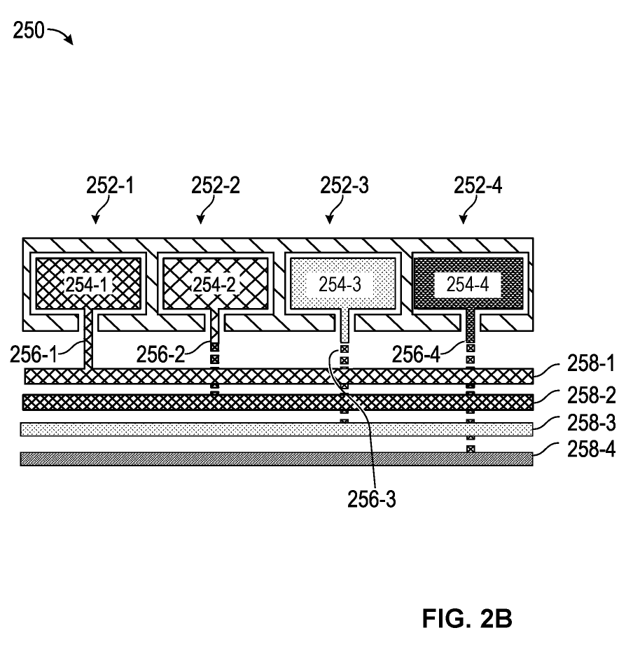

FIGS. 2A and 2B are plan views of example MEMS arrays 200/250.

As shown in FIG. 2A, the MEMS array 200 includes an electrode configuration of a set of MEMS mirror devices 202, such as MEMS mirror device 202-1, MEMS mirror device 202-2, and MEMS mirror device 202-N. Each MEMS device 202 includes a corresponding X-electrode 204 and a corresponding Y-electrode 206. For example, the MEMS mirror device 202-1 includes an X-electrode 204-1 and a Y-electrode 206-1. The MEMS array 200 includes an X-pad 208 and a Y-pad 210 that connect to the X-electrodes 204 and the Y-electrodes 206 via an X-bus 212 and aY-bus 214, respectively. As shown, the X-electrodes 204 connect to the X-bus 212 via planar electrical traces 216. In contrast, the Y-electrodes 206 connect to the Y-bus 214 via non-planar electrical traces 218. For example, the non-planar electrical traces 218 may include three- dimensional traces, as described herein.

As shown in FIG. 2B, the MEMS array 250 includes a set of individually addressable MEMS actuating elements 252, such as MEMS actuating element 252-1, MEMS actuating element 252-2, MEMS actuating element 252-3, and MEMS actuating element 252-4. Each MEMS actuating element 252 includes a corresponding electrode 254 and trace 256. For example, the MEMS actuating element 252-1 includes an electrode 254-1 associated with a trace 256-1. The MEMS array 250 includes a set of buses 258 that correspond to the set of MEMS actuating elements 252. For example, the electrode 254-1, of the MEMS actuating element 252- 1, connects to the bus 258-1 (and onward to, for example, a pad). As shown, the electrode 254-1 connects to the bus 258-1 via a planar electrical trace 256-1. In contrast, the other electrodes 254 connect to correspond buses 258 via non-planar traces 256. For example, the electrode 254-2, of the MEMS actuating element 252-2, may connect to the bus 258-2 via a three-dimensional trace 256-2, the electrode 254-3, of the MEMS actuating element 252-3, may connect to the bus 258-3 via a three-dimensional trace 256-3, and the electrode 254-4, of the MEMS actuating element 252-4, may connect to the bus 258-4 via a three-dimensional trace 256-4. In this way, a MEMS array 250 can achieve individual control of MEMS optical elements that are actuated by MEMS actuating elements.

As indicated above, FIGS. 2A and 2B are provided as examples. Other examples may differ from what is described with regard to FIGS. 2A and 2B.

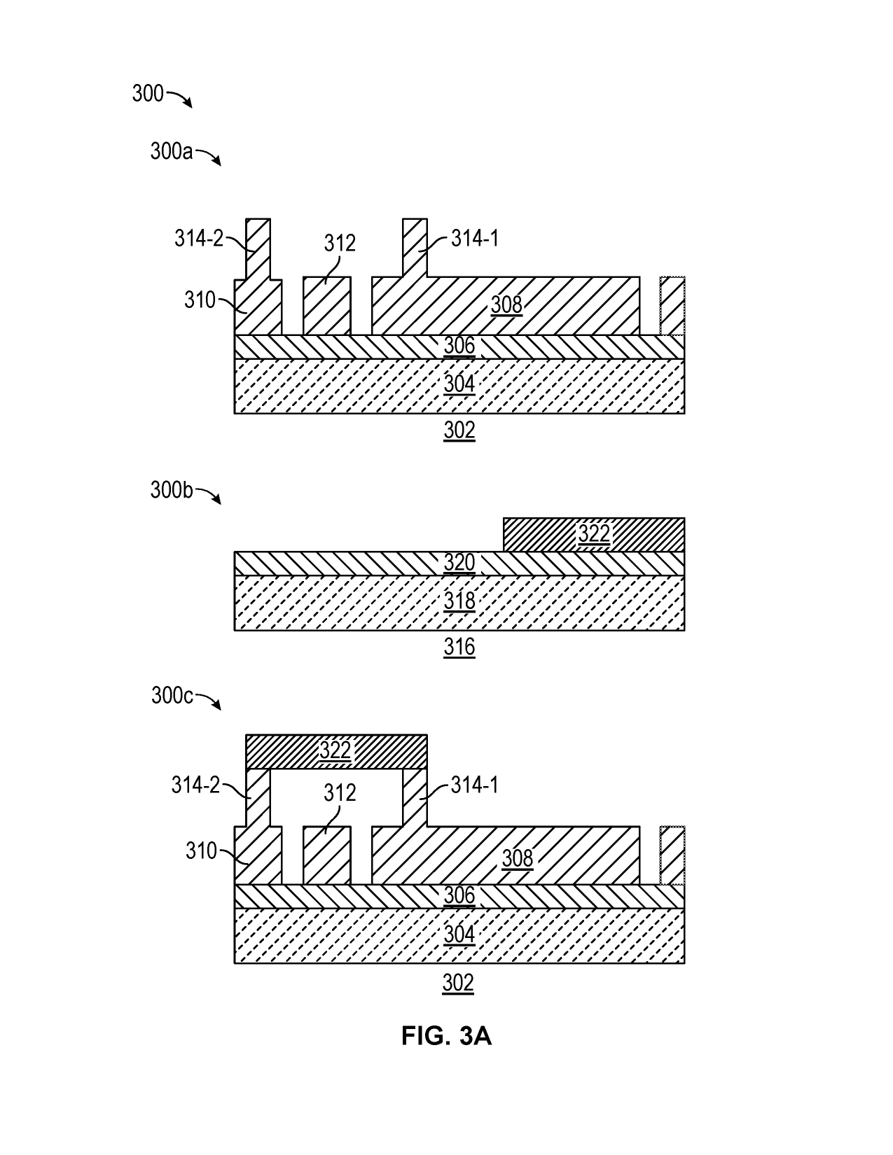

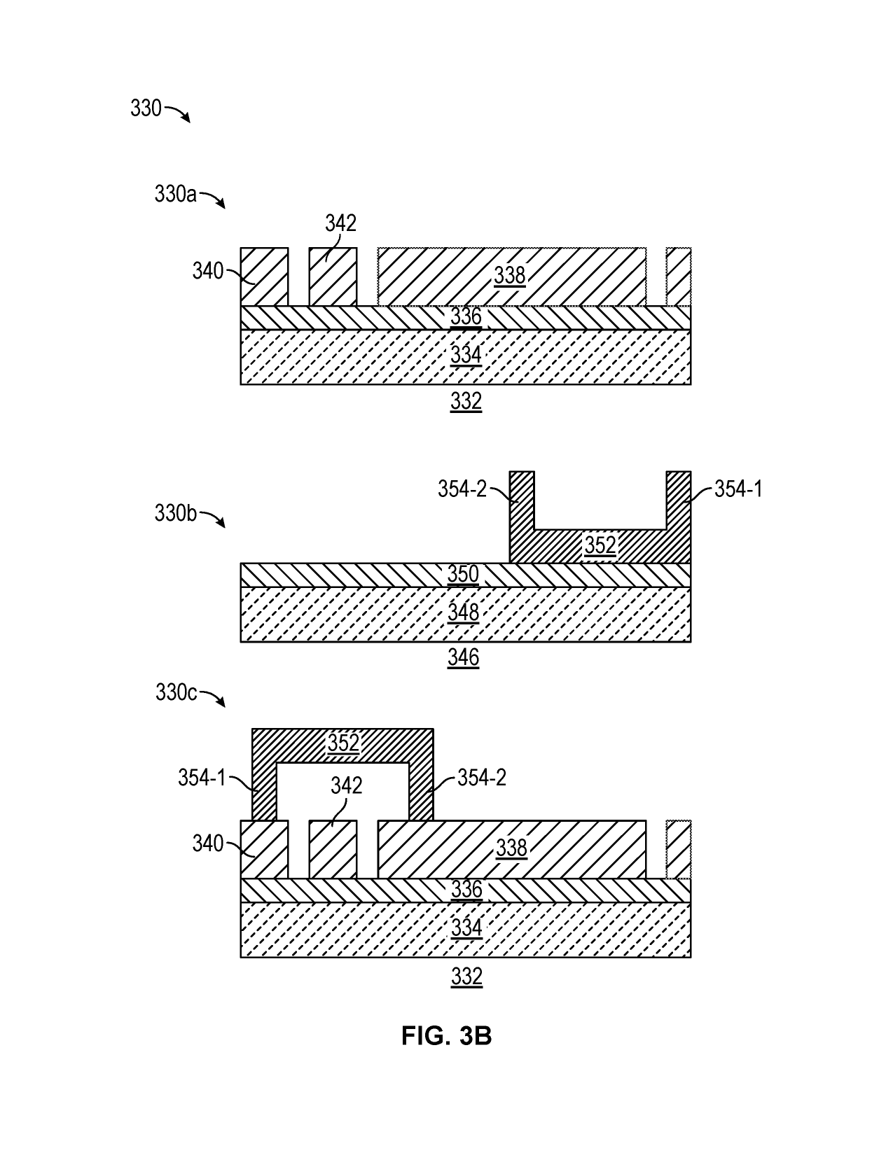

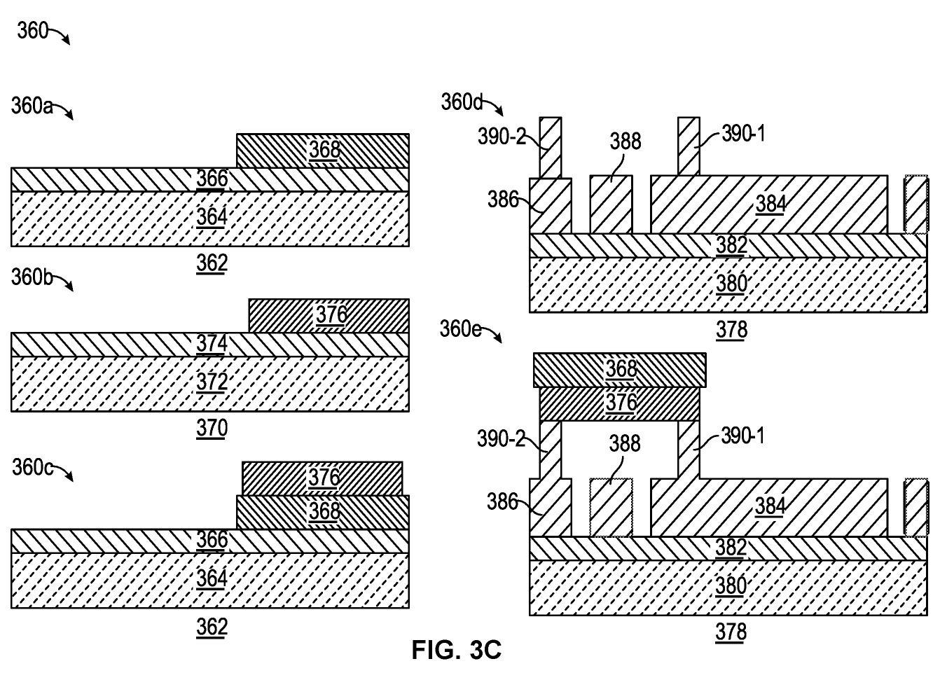

FIGS. 3A-3C are diagrams of examples of assembling an optical device with a three- dimensional trace.

As shown in FIG. 3A, in a first example 300 and in a step 300a, a first wafer 302 is formed with a first handle 304 and a first insulation layer 306. A material deposition process or etching process may form, on the first insulation layer 306 and at a particular cross-sectional position, a set of features, such as a Y-electrode 308, a Y-bus 310, an X-bus 312, and a set of posts 314-1 and 314-2. In some implementations, the set of posts 314 are formed monolithically with respect to an electrode layer. For example, a deposition layer may deposit a single layer of material, which may be etched to form the set of features (e.g., the Y-electrode 308, the Y-bus 310, the X-bus 312, and the set of posts 314-1 and 314-2). In other words, rather than the posts 314 being formed as separate layers on top of an electrode layer (e.g., the Y-electrode 308, the Y- bus 310, the X-bus 312), the posts 314 are formed continuous with features of the electrode layer, as shown. As further shown in FIG. 3A, in a step 300b, a second wafer 316 is formed with a second handle 318, and a second insulation layer 320. A material deposition process or etching process may form, on the second insulation layer 320 and at a particular cross-sectional position, a bridge 322. As further shown in FIG. 3A, in a step 300c, the bridge 322 is attached to the posts 314 to form a three-dimensional trace. For example, the second wafer 316 may be flipped upside-down with respect to the first wafer 302 and may be attached to the first wafer 302, such as by wafer-bonding. A layer removal step, such as an etching process, may remove the second handle 318 and the second insulation layer 320 to expose the bridge 322, as shown.

As shown in FIG. 3B, in a second example 330 and in a step 330a, a first wafer 332 is formed with a first handle 334 and a first insulation layer 336. A material deposition process or etching process may form, on the first insulation layer 336 and at a particular cross-sectional position, a set of features, such as a Y-electrode 338, a Y-bus 340, and an X-bus 342. As further shown in FIG. 3B, in a step 330b, a second wafer 346 is formed with a second handle 348, and a second insulation layer 350. A material deposition process or etching process may form, on the second insulation layer 350 and at a particular cross-sectional position, a bridge 352 and a set of posts 354-1 and 354-2. In some implementations, the set of posts 354 are formed monolithically with respect to the bridge 352. For example, a deposition layer may deposit a single layer of material, which may be etched to form the set of features (e.g., the bridge 352 and the posts 354). In other words, rather than the posts 354 being formed as separate structures that are attached to the bridge 322, the posts 354 are formed continuous with the bridge 352, as shown. As further shown in FIG. 3B, in a step 330c, the bridge 352 and the posts 354 are attached to the first wafer 332 to form a three-dimensional trace between the Y-electrode 338 and the Y-bus 340. For example, the second wafer 346 may be flipped upside-down with respect to the first wafer 332 and may be attached to the first wafer 332, such as by wafer-bonding. A layer removal step, such as an etching process, may remove the second handle 348 and the second insulation layer 350 to expose the bridge 352 and the posts 354, as shown.

As shown in FIG. 3C, in a third example 360 and in a step 360a, a first wafer 362 is formed with a first handle 364, and a first insulation layer 366. A material deposition process or etching process may form, on the second insulation layer 320 and at a particular cross-sectional position, a first bridge layer 368. As further shown in FIG. 3C, in a step 360b, a second wafer 370 is formed with a second handle 372, and a second insulation layer 374. A material deposition process or etching process may form, on the second insulation layer 374 and at a particular cross-sectional position, a second bridge layer 376. As further shown in FIG. 3C, in a step 360c, the second bridge layer 376 is attached to the first bridge layer 368 to form a multi- layer bridge with a top bridge component and a bottom bridge component. For example, the second wafer 370 may be flipped upside-down with respect to the first wafer 362 and may be attached to the first wafer 362, such as by wafer-bonding. A layer removal step, such as an etching process, may remove the second handle 372 and the second insulation layer 374 to expose the second bridge layer 376, as shown.

As further shown in FIG. 3C, in a step 360d, a third wafer 378 is formed with a third handle 380 and a third insulation layer 382. A material deposition process or etching process may form, on the third insulation layer 382 and at a particular cross-sectional position, a set of features, such as a Y-electrode 384, a Y-bus 386, an X-bus 388, and a set of posts 390-1 and 390- 2. In some implementations, the set of posts 390 are formed monolithically with respect to an electrode layer, as described above. As further shown in FIG. 3C, in a step 360e, the bridge layers 376 and 368 are attached to the posts 390 to form a three-dimensional trace. For example, the first wafer 362 may be flipped upside-down with respect to the third wafer 378 and may be attached to the third wafer 378, such as by wafer-bonding. A layer removal step, such as an etching process, may remove the first handle 364 and the first insulation layer 366 to expose the bridge layer 368 and the bridge layer 376, as shown.

As indicated above, FIGS. 3A-3C are provided as examples. Other examples may differ from what is described with regard to FIGS. 3A-3C.

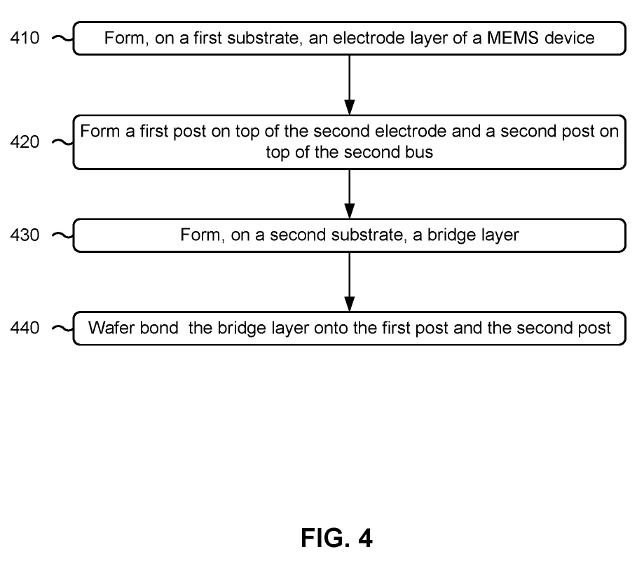

FIG. 4 is a flowchart of an example process 400 associated with manufacturing a MEMS device with a three-dimensional trace. One or more process blocks of FIG. 4 are performed by a manufacturing device (e.g., a wafer deposition device, an etching device, or a wafer bonding device) and/or by another device or a group of devices separate from or including the manufacturing device.

As shown in FIG. 4, process 400 includes forming an electrode layer of a MEMS device, wherein the electrode layer includes a first electrode and a second electrode (block 410). For example, the manufacturing device may form an electrode layer of a MEMS device, as described above. In some implementations, the electrode layer includes a first electrode and a second electrode, wherein the first electrode is connected to a first bus and the second electrode is connected to a second bus. In some implementations, the first electrode corresponds to a first actuating element, movable element, or tilting comb and the second electrode corresponds to a second actuating element, movable element, or tilting comb.

As further shown in FIG. 4, process 400 includes forming a first post on top of the second electrode and a second post on top of the second bus (block 420). For example, the manufacturing device may form a first post on top of the second electrode and a second post on top of the second bus, as described above. In some implementations, the manufacturing device may form the first post integrally with forming the second electrode and/or the second bus. In other words, rather than depositing the first post on top of the second electrode, the manufacturing device may form the second electrode and the post in a single set of deposition steps, etching steps, or other manufacturing steps, such that the first post is a part of the second electrode rather than attached to the second electrode (e.g., via an adhesive). Additionally, or alternatively, the first post may be a separate layer of material that is adhered to the second electrode (e.g., via an adhesive).

As further shown in FIG. 4, process 400 includes forming a bridge layer (block 430). For example, the manufacturing device may form a bridge layer on a second substrate, as described above. In some implementations, the bridge layer may be integral with the second post. In some implementations, the bridge layer may be adhered to the second post. In some implementations, the bridge layer may be a multi-layer bridge, which may provide stability improvement, conductivity improvement, or adhering improvement relative to a single-layer bridge.

As further shown in FIG. 4, process 400 includes wafer bonding the bridge layer onto the first post and the second post (block 440). For example, the manufacturing device may wafer bond the bridge layer onto the first post and the second post, such that the first post is electrically connected to the second post by the bridge layer, as described above.

Process 400 may include additional aspects, such as any single aspect or any combination of aspects described below and/or in connection with one or more other processes described elsewhere herein.

In a first aspect, process 400 includes removing the second substrate to expose a side of the bridge layer.

In a second aspect, alone or in combination with the first aspect, process 400 includes attaching a MEMS optical element to the electrode layer, such that the MEMS optical element is movable by the first electrode and the second electrode.

In a third aspect, alone or in combination with one or more of the first and second aspects, forming the bridge layer comprises depositing a bridge bottom layer on the second substrate, and depositing a bridge top layer on the bridge bottom layer.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

s used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to "at least one of' a list of items refers to any combination of those items, including single members. As an example, "at least one of: a, b, or c" is intended to cover a, b, c, a-b, a-c, b-c, and a-b-c, as well as any combination with multiple of the same item.

When a component or one or more components (e.g., a manufacturing device or one or more manufacturing devices) is described or claimed (within a single claim or across multiple claims) as performing multiple operations or being configured to perform multiple operations, this language is intended to broadly cover a variety of architectures and environments. For example, unless explicitly claimed otherwise (e.g., via the use of "first component" and "second component" or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form "one or more components configured to: perform X; perform Y; and perform Z," that claim should be interpreted to mean "one or more components configured to perform X; one or more (possibly different) components configured to perform Y; and one or more (also possibly different) components configured to perform Z."

No element, act, or instruction used herein should be construed as critical or essential unless explicitly described as such. Also, as used herein, the articles "a" and "an" are intended to include one or more items, and may be used interchangeably with "one or more." Further, as used herein, the article "the" is intended to include one or more items referenced in connection with the article "the" and may be used interchangeably with "the one or more." Furthermore, as used herein, the term "set" is intended to include one or more items (e.g., related items, unrelated items, or a combination of related and unrelated items), and may be used interchangeably with "one or more." Where only one item is intended, the phrase "only one" or similar language is used. Also, as used herein, the terms "has," "have," "having," or the like are intended to be open-ended terms. Further, the phrase "based on" is intended to mean "based, at least in part, on" unless explicitly stated otherwise. Also, as used herein, the term "or" is intended to be inclusive when used in a series and may be used interchangeably with "and/or," unless explicitly stated otherwise (e.g., if used in combination with "either" or "only one of'). Further, spatially relative terms, such as "below," "lower," "above," "upper," and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A micro-electromechanical system (MEMS) mirror device, comprising:
a hinged mirror;
a first set of actuating elements,
wherein the first set of actuating elements is associated with a first set of electrodes connected to a first bus;
a second set of actuating elements,
wherein the second set of actuating elements is associated with a second set of electrodes connected to a second bus; and
a set of three-dimensional traces electrically connecting the second set of electrodes to the second bus without touching the first bus,
wherein a three-dimensional trace, of the set of three-dimensional traces, includes a pair of posts extending vertically from the second bus and the second set of electrodes, respectively, and includes a bridge connecting the pair of posts.

2. The MEMS mirror device of claim 1, wherein the first set of actuating elements is configured to tilt the hinged mirror about a first axis, and wherein the second set of actuating elements is configured to tilt the hinged mirror about a second axis.

3. The MEMS mirror device of claim 2, wherein the second axis is orthogonal to the first axis.

4. The MEMS mirror device of claim 1, wherein the second bus is oriented parallel to the first bus, such that the first bus is disposed between the first set of electrodes and the second bus and is disposed between the second set of electrodes and the second bus.

5. The MEMS mirror device of claim 1, the bridge includes a top bridge component and a bottom bridge component.

6. The MEMS mirror device of claim 1, wherein the bridge includes a silicon material.

7. The MEMS mirror device of claim 1, wherein the pair of posts are formed monolithically with the second bus and the second set of electrodes.

8. The MEMS mirror device of claim 7, wherein the bridge is wafer-bonded to the pair of posts.

9. The MEMS mirror device of claim 1, wherein the pair of posts are formed monolithically with the bridge as an assembly.

10. The MEMS mirror device of claim 9, wherein the assembly is wafer-bonded to the second bus and the second set of electrodes.

11. A micro-electromechanical system (MEMS) device, comprising:
a movable element; and
an actuating layer disposed below the movable element and comprising:
a first set of actuating elements configured to move the movable element in a first direction,
wherein the first set of actuating elements is associated with a first set of electrodes connected to a first bus via a first set of electrical traces,
a second set of actuating elements configured to move the movable element in a second direction,
wherein the second set of actuating elements is associated with a second set of electrodes connected to a second bus via a second set of electrical traces,
wherein the second set of electrical traces is disposed at least partially above the first bus.

12. The MEMS device of claim 11, wherein the first set of electrical traces are disposed in a plane of the actuating layer, and wherein the second set of electrical traces includes at least a portion disposed at least partially in a plane other than the plane of the actuating layer.

13. The MEMS device of claim 11, wherein an electrical trace, of the second set of electrical traces, includes:
a first post extending vertically from a corresponding electrode of the second set of electrodes;
a second post extending vertically from the second bus; and
a bridge extending laterally between the first post and the second post, such that the bridge crosses over the first bus without contacting the first bus.

14. The MEMS device of claim 13, wherein the bridge is disposed co-planar with the movable element.

15. The MEMS device of claim 13, wherein the movable element includes an opening to receive the bridge.

16. The MEMS device of claim 13, wherein the bridge is formed with the movable element and detached from the movable element, such that the bridge is not electrically connected to the movable element.

17. A method, comprising:
forming, by a manufacturing device on a first substrate, an electrode layer of a micro- electromechanical system (MEMS) device,
wherein the electrode layer includes a first electrode and a second electrode,
wherein the first electrode is connected to a first bus and the second electrode is connected to a second bus;
forming, by the manufacturing device, a first post on top of the second electrode and a second post on top of the second bus;
forming, by the manufacturing device on a second substrate, a bridge layer; and
wafer bonding, by the manufacturing device, the bridge layer onto the first post and the second post, such that the first post is electrically connected to the second post by the bridge layer.

18. The method of claim 17, further comprising:
removing the second substrate to expose a side of the bridge layer.

19. The method of claim 17, further comprising:
attaching a MEMS optical element to the electrode layer, such that the MEMS optical element is movable by the first electrode and the second electrode.

20. The method of claim 17, wherein forming the bridge layer comprises:
depositing a bridge bottom layer on the second substrate; and
depositing a bridge top layer on the bridge bottom layer.
